(19) United States
(12) Patent Application Publication
(10) Pub. No.: US 2002/0167068 A1
(43) Pub. Date: Nov. 14, 2002

(54) Silicon on sapphire structure (devices) with buffer layer

(75) Inventors: Louis L. Hsu, Fishkill, NY (US); Leathen Shi, (US); Li-Kong Wang, Montvale, NJ (US)

Correspondence Address: Louis J. Percello, Intellectual Property Law Dept., IBM Corporation, P.O. Box 218, Yorktown Heights, NY, 10598, US

(73) Assignee: International Business Machines Corporation, Armonk, NY

(21) Appl. No.: 09/852,362

(22) Filed: May 9, 2001

(51) Int. Cl. H01L 27/108

(52) U.S. Cl. 257/507; 257/297; 257/349; 257/728; 257/347; 257/352

(57) ABSTRACT

An improved silicon on sapphire structure and/or device has one or more buffer layers. In a first preferred embodiment, the buffer layer is layer of silicon oxide material that prevents the stress induced defects in the silicon layer. In an alternative embodiment, the buffer layer comprises two layers. A first silicon oxide layer attached to the silicon to insure a perfect interface between the silicon. A second silicon oxide layer then is attached to the sapphire layer. The first and second silicon oxide layers are then attached, e.g., by a wafer bonding technique. This structure has no conductive paths beneath the oxide insulator(s) and therefore enables improved performance in radio frequency applications.

### FIELD OF THE INVENTION

This invention relates to the field of integrated circuitry. More specifically, the invention relates to the field of integrated circuits used in radio frequency applications.

### BACKGROUND OF THE INVENTION

CMOS devices built on the silicon on insulator (SOI) substrates can have enhanced performance due to reduction of parasitic capacitance and increase of carrier mobility. This kind of high performance device and circuit technology at present can be applied to operate at GHz RF applications. Integration of RF passive components with this kind of technology enables high performance, high integration level, low cost RF integrated circuits. However most of the chips today are built on silicon based substrate, including those on SOI wafers. This becomes a major drawback in RF applications because the conducting silicon substrate becomes a lose path in the substrate when the circuit and passive components are switching at RF frequency. A typical example is the inductor induced Eddy current in the substrate from the current flowing in the coil. The reduction of the Q factor due to the energy loss in the substrate can significantly downgrade the efficiency of the circuits. Building devices and components on an insulating substrate can not only reduce dissipation loss and but also the insulator substrate is transparent to the RF wave signals. Sapphire is a highly transparent material at RF frequency with excellent insulating property. To build silicon devices on sapphire substrate has been successfully demonstrated for many years.

The material mismatch between silicon device layer and the underneath sapphire can greatly degrade the possibility to make high quality devices. This is because the material mismatch between the silicon and sapphire layer causes defects in the silicon device like dislocations, cracks, and/or leakage currents. Also, the present melting and re-crystallization approach to fabricate silicon on sapphire substrates significantly increasing the defect density in the silicon device layer.

### OBJECTS OF THE INVENTION

An object of this invention is an improved silicon on sapphire structure (device).

An object of this invention is an improved a silicon on sapphire structure (device) with a reduced mismatch between the silicon and the sapphire layers.

An object of this invention is an improved silicon on sapphire structure (device) made without melting and re-crystallization of the layers.

An object of this invention is an improved silicon on sapphire structure (device) with an oxide layer in between the silicon and sapphire layers.

An object of this invention is an improved a silicon on sapphire structure (device) used in radio frequency applications.

An object of this invention is an improved silicon on sapphire structure (device) with two separate and adjacent oxide layers, one on the silicon layer and one on the sapphire substrate

### SUMMARY OF THE INVENTION

The present invention is an improved silicon on sapphire structure and/or device with one or more buffer layers. In a first preferred embodiment, the buffer layer is layer of silicon oxide material that prevents the stress induced defects in the silicon layer. In an alternative embodiment, the buffer layer comprises two layers. A first silicon oxide layer attached to the silicon to insure a perfect interface between the silicon and the oxide layer. A second silicon oxide layer then is attached to the sapphire layer. The first and second silicon oxide layers are then attached, e.g., by a wafer bonding technique. This structure has no conductive paths beneath the oxide insulator(s) and therefore enables improved performance in radio frequency applications.

### BRIEF DESCRIPTION OF THE FIGURES

FIG. 1 is a block diagram perspective view of a silicon on sapphire film structure with a one layer silicon oxide bonding interface.

FIG. 2 is a block diagram perspective view of a silicon on sapphire film structure with a dual layer silicon oxide bonding interface.

### DETAILED DESCRIPTION OF THE INVENTION

In the present invention passive components are built on sapphire substrates. The silicon layer containing devices on the sapphire substrate is defect free in contrast to the other structures, and the sapphire substrate is totally transparent to RF radiation and optical light. Although the sapphire is our choice at this point as the substrate material, many other types of insulator substrates can also substitute the sapphire substrate used here as well. For example, silicate glass, plastic, or any organic material like polyamide. However, sapphire is a preferred embodiment because it has excellent thermal conductivity.

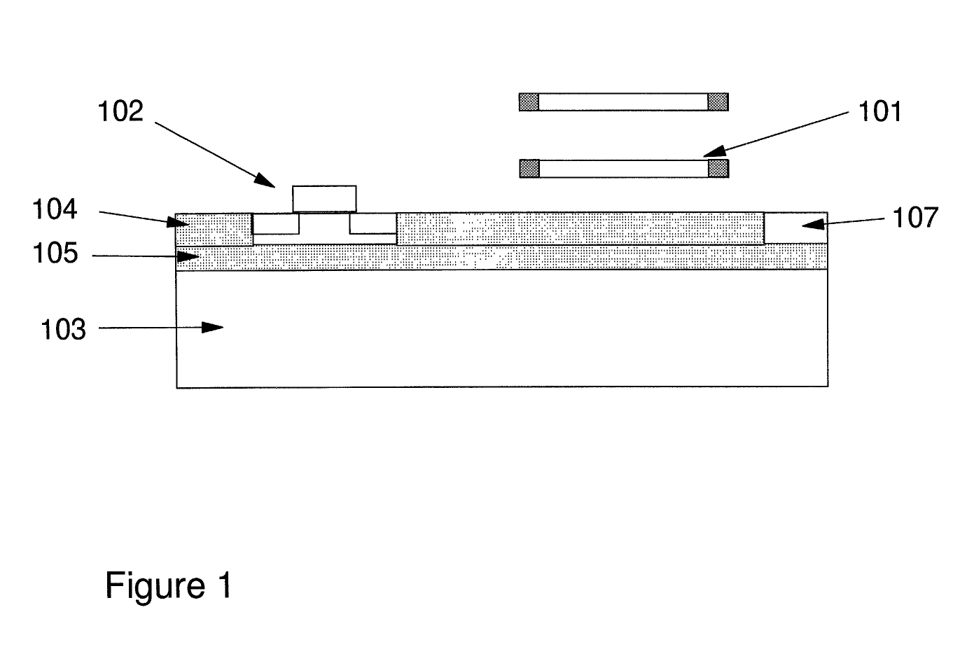

The film structure of the silicon 107 on sapphire 103 is shown in FIG. 1. The buffer layer 105 between the silicon 107 and the sapphire 103 are thermal grown oxide.

This layer 105 can provide improved adhesive property when the substrate 103 is annealed during the device fabrication procedure. Also, it 105 serves as a stress relieve layer to reduce the thermal mismatch induced defects during annealing process. This silicon oxide layer is designed to provide a viscous layer between the device-layer 107 to the sapphire 103 to absorb the thermal induced stress between the two layers (103, 107).

The CMOS FET devices 102 are fabricated on the sapphire substrate 103 in the silicon layer 107. Between devices the isolation oxide 104 is either deposited or filled with a shallow trench isolation (STI) process or known equivalent. A representative passive component (inductive coil) is shown as 101. The oxide layers serves as the buffer layers 105 between the sapphire substrate 103 and the silicon device layer 107. The silicon dioxide layer 105 is thermally grown from the silicon to preserve good interface property and device characteristics.

A layer of silicon dioxide 105 is grown on the device wafer 107 to make good oxide to device interface properties. The thickness of this layer can be as thin as 10-20 angstrom to 1 micron or greater. By growing the silicon dioxide layer 105 on the device wafer 107 a perfect crystal interface is created between the silicon dioxide layer 105 and the silicon device layer 107. In alternative embodiments, the silicon dioxide layer 105 is deposited on the device layer 107 by known techniques. In these processes, the interface between the silicon dioxide layer 105 and the device layer 107 may not be a perfect crystal interface.

The silicon wafer and the sapphire 103 are bonded together and annealed to promote the adhesiveness according to well known techniques.

By using a Chemical Mechanical Polishing (CMP) process, most of the material of the silicon device wafer can be remove to the thin final layer 107 at the thickness desired. After that a patterned Shallow Trench Isolation process is used to form the isolation 104 between devices as indicated. Of course, other methods such as local oxidation also can be used to make this isolation structure.

The CMOS devices 102 can be fabricated using a conventional processing.

The passive components 101, (capacitors, inductors, resistors, etc.) can be fabricated together with the device interconnect process. An example of planar coil 101 is shown. Since there is no underlying conductive substrate, there is no Eddy current type of loss of RF signal.

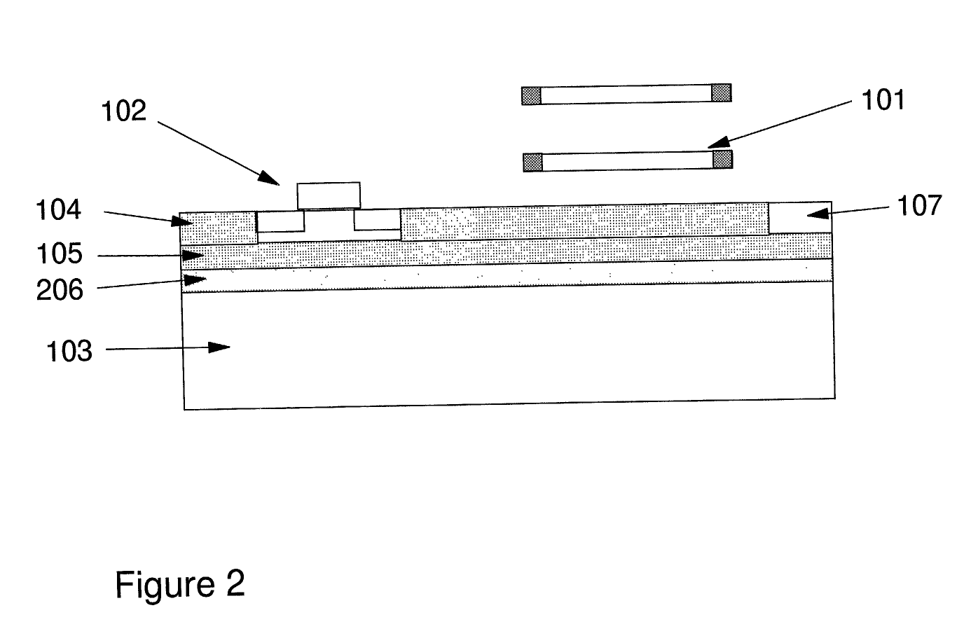

FIG. 2 is a block diagram perspective view of an alternative preferred embodiment with two oxide buffer layers. Components that are the same as those in FIG. 1, have the same reference numbers and description as that in FIG. 1. These two layers (105, 206) can provide improved adhesive property when the substrate is annealed during the device fabrication procedure. Also, they (105, 206) serve as a stress relieve buffer layer to reduce the thermal mismatch induced defects during annealing process. In a preferred embodiment, the upper silicon oxide layer 105 which directly interfaces with silicon layer 107 is thermally grown from the silicon film 107 to provide good interface between the silicon device layer 107 to the upper oxide layer 105. In a preferred embodiment, the bottom silicon oxide layer 206 is a deposited oxide that is typically done in a Low Pressure Chemical Vapor Deposition (LPCVD) process or a Plasma Enhanced Chemical Vapor Deposition (PECVD) process, or equivalent. This silicon oxide layer 206 is designed to provide a viscous layer between the silicon device-layer 107 and the sapphire 103 to absorb the thermal induced stress between the two layers (103, 107). In alternative embodiments, layer 105 can be deposited.

The CMOS FET devices 102 are fabricated on the sapphire substrate 103 in the silicon layer 107. Between devices 102 the isolation oxide 104 is either deposited or filled with a shallow trench isolation (STI) process or known equivalent. A representative passive component (inductive coil) is shown as 101. There two oxide layers (105, 206) serve as the buffer layers between the substrate 103 and the silicon device layer 107.

The thickness of layer 105 can be for 10-20 angstroms to 1 micron or above. The thickness of the deposited oxide can be from 100-200 angstroms to several microns and above.

By using a Chemical Mechanical Polishing (CMP) process, most of the material of the silicon device wafer can be remove to the thin final layer 107 to produce the thickness desired. After that a patterned Shallow Trench Isolation process is used to form the isolation 104 between devices as indicated. Of course, other methods, such as local oxidation, also can be used to make this isolation structure 104. In a preferred embodiment, the isolation structure 104 is silicon oxide or other dielectric material as is commonly used in the art.

Therefore, in both the single layer buffer and the double layer buffer embodiment the isolation sections 104, the silicon oxide layer(s) (105 or 105 and 206), and the sapphire layer 103 are insulating layers that provide no electrical conductivity between the electrical components (101, 102). However, these layers (103, 104, 105, and 206) are transparent to electromagnetic energy, particularly radio frequency energy and still provide a defect free interface between the silicon device layer 107 and the substrate 103.

The method of making these structures is further described and claimed in U.S. patent application Ser. No. ______, entitled Method of Fabricating Silicon Devices on Sapphire with Wafer Bonding to same inventors, which is herein incorporated by reference in its entirety.

Given this disclosure other embodiments of the invention will become apparent. These embodiments are also within the contemplation of the inventors.

We claim:

1. A silicon on sapphire structure comprising:
a silicon layer;
a sapphire layer; and
an insulating layer sandwiched between the silicon and sapphire layer.

2. A structure, as in claim 1, where the insulating layer is a silicon oxide-silicon interface between the silicon layer and the sapphire layer that provides a crystal interface between the insulating layer and the silicon.

3. A structure, as in claim 2, where the silicon oxide-silicon interface is created by growing the silicon oxide layer on the silicon layer.

4. A structure, as in claim 1, where the insulating layer is a silicon oxide layer and the interface between the silicon oxide layer and the silicon and the silicon layer is not a crystal interface.

5. A structure, as in claim 4, where the silicon oxide-silicon interface is created by depositing the silicon oxide layer on the silicon layer.

6. A structure, as in claim 1, where the silicon layer comprises one or more component islands made of silicon and one or more isolation sections between the silicon islands, the isolation sections being made of silicon oxide.

7. A structure, as in claim 6, where at least one of the component islands is used to form one or more electrical components that are isolated by the silicon oxide layer and the sapphire layer.

8. A structure, as in claim 7, where at least one of the isolation sections comprises the silicon oxide layer and the sapphire layer and the isolation sections are insulating layers that are used to form passive devices.

9. A structure, as in claim 8, where the passive devices comprise any one or more of the following: a capacitor, an inductor, and a resistor.

10. A silicon on sapphire structure comprising:
a silicon layer;
a sapphire layer; and
a buffer layer sandwiched between the silicon and sapphire layer, the buffer layer comprising a first dielectric layer attached to the silicon layer and a second dielectric layer attached to the sapphire layer, the first and second dielectric layers being attached to one another.

11. A structure, as in claim 9, where the first dielectric layer is a silicon oxide-silicon layer providing a perfect crystal interface between the silicon layer and the first dielectric layer.

12. A structure, as in claim 11, where the silicon oxide of the first dielectric layer is created by growing the silicon oxide layer on the silicon layer.

13. A structure, as in claim 10, where the first dielectric layer is a silicon oxide layer bound to the silicon layer as a crystal interface.

14. A structure, as in claim 13, where the interface between the silicon oxide layer and the silicon layer is created by depositing the silicon oxide layer on the silicon layer.

15. A structure, as in claim 10, where the silicon layer comprises one or more component islands made of silicon and one or more isolation sections between the silicon islands, the isolation section being made of silicon oxide.

16. A structure, as in claim 15, where one or more of the component islands is an electrical component and the isolation sections, the silicon oxide layer, and the sapphire layer are insulating layers that provide no electrical conductivity between the electrical components.

17. A structure, as in claim 16, where a radio frequency wave can communicate with one or more of the electrical components through the insulating layers.

18. A structure, as in claim 10, where the interface between the second dielectric layer and the sapphire layer is not a crystal interface.

19. A structure, as in claim 18, where the interface between the second dielectric layer and the sapphire layer is created by depositing the second dielectric layer on the sapphire layer.

20. A structure, as in claim 10, where the silicon layer comprises one or more component islands made of silicon and one or more isolation sections between the silicon islands, the isolation sections being made of silicon oxide.

21. A structure, as in claim 20, where at least one of the isolation sections is used to form one or more passive electrical components.

22. A structure, as in claim 21 where the passive electrical components include any one or more of the following: a resister, a capacitor, and an inductor.
